(19) United States
(12) Patent Application Publication
(10) Pub. No.: US 2018/0001349 A1
(43) Pub. Date: Jan. 4, 2018

(54) DIRECTIONALLY ORIENTED PIEZOELECTRIC MATERIALS AND METHODS OF FABRICATION

(71) Applicant: Eric A. Burgett, Pocatello, ID (US)

(72) Inventor: Eric A. Burgett, Pocatello, ID (US)

(21) Appl. No.: 15/622,482

(22) Filed: Jun. 14, 2017

Related U.S. Application Data
(60) Provisional application No. 62/349,930, filed on Jun. 14, 2016.

(51) Int. Cl. B06B 1/06; H01L 41/187; C30B 29/68; H01L 41/253; C30B 25/02

(52) U.S. Cl. CPC B06B 1/0644; H01L 41/253; C30B 25/02; C30B 29/68; H01L 41/1873

(57) ABSTRACT

Using a chemical vapor-phase deposition (CVD), physical vapor phase deposition (PVD) process or similar, novel directionally-oriented piezoelectric materials are created from zinc oxide (ZnO) and similar materials with innovative features that enhance their performance as ultrasonic transducers. Applications for these enhanced piezoelectric materials and transducers include: underwater sonar devices, non-destructive testing devices, tank level indicators, eddy current detectors, ultrasonic wellfield characterization devices, and in-fluid imaging devices (e.g., under-water and under-sodium viewing devices).

### BACKGROUND OF THE INVENTION

The ultrasonic transducer described below is a device which makes different forms of physical waves with different shapes, amplitudes, frequencies and waveforms which can be repeating or arbitrary in nature. Their frequency is above that of the audible range for humans extending from 10s of kHz to the GHz and THz levels. These physical waves propagate through matter and produce different effects. They can produce heat, resonate solid, liquid and gas molecules, reflect and refract off different material interfaces, and get absorbed in materials among other things. These physical waves can be created unidirectionally in 3D space or omnidirectionally. In non-destructive testing, biomedical applications, and imaging applications, the ultrasound waves reflect and refract off of different material types, densities, and compositions. In pulse echo mode, these reflections are observed. In pulse transmission mode, the attenuation of the waves is observed as well as any refraction, scattering, and other terms. Combining the two modes yields the most information about the material.

### FIELDS OF USE

The directionally-oriented piezoelectric materials described herein have potential application in the following fields of use: Precision motors and positioning devices; Scientific Instruments (e.g., acoustic microscopy); Non-destructive testing (e.g., detection of delamination, inclusions and/or voids in in advanced ceramics, metal alloys, advanced composites; determination of weld quality in joined materials; eddy current detectors); Particle manipulation and characterization (e.g., nano-particles); Sensors (e.g., process control sensors like tank level indicators, fluid flow detection, fluid flow measurement, position detection, range measurement, dimension measurement (e.g., length, width, thickness); automobile parking and collision sensors); Joining and welding of similar and dissimilar materials (e.g., metals, alloys, hard and soft plastics, thermoplastics, carbon-fiber composites, advanced composites); Under-liquid viewing (e.g., water, sodium, liquid metals, molten salts); Object detection, characterization and identification (e.g. particles in fluids); Medical imaging; Medical Diagnosis and Therapy (e.g., disintegration and destruction of cancer cells, growths, tumors, cysts, inclusions, and deposits); Oil and Gas exploration and production (e.g., ultrasonic wellfield characterization devices); Chemical processes (e.g., solution agitation and mixing; direct and indirect inducement of chemical reactions; manipulation of molecular-level chemical behavior); semiconductor-based piezotronics.

### Generic Description of Field

Ultrasound is defined by the American National Standards Institute as “sound at frequencies greater than 20 kHz.” The first demonstration of the direct piezoelectric effect (mechanical deformation causing electrical potential) was in 1880 by the brothers Pierre Curie and Jacques Curie. The converse effect (electrical potential causing mechanical deformation) was mathematically deduced from fundamental thermodynamic principles by Gabriel Lippmann in 1881. The Curies immediately confirmed the existence of the converse effect, and went on to obtain quantitative proof of the complete reversibility of deformations in piezoelectric crystals. In 1910, Woldemar Voigt published Lehrbucli der Kristallphysik (Textbook on Crystal Physics), which described the 20 natural crystal classes capable of piezoelectricity, and rigorously defined the piezoelectric constants using tensor analysis. The first significant use of piezoelectric materials was the development of sonar systems around the time of World War I, which saw significant development and use in World War II. Medical applications of ultrasound was begun by Dr. George Ludwig at the Naval Medical Research Institute in the late 1940s. The physicist John Wild is known as the father of medical ultrasound for imaging tissue in 1949. In addition, Dr. Karl Theodore Dussik of Austria published the first paper on medical ultrasonics in 1942, based on his research on transmission ultrasound investigation of the brain; and Professor Ian Donald of Scotland developed practical technology and applications for ultrasound in the 1950s. (See: www.thoughtco.com/history-of-ultrasound-in-medicine-1991660). Other applications of ultrasound were developed in the 1960s like non-destructive testing and sensors and control devices and development of these and other applications continues to this day.

Modern ultrasonic devices are made from piezoelectric materials; materials that vibrate when an alternating electric voltage is applied to them. Typical piezoelectric materials can be crystals such as quartz and lead titanate; biological materials such as silk; synthetic crystals such as lithium niobate; synthetic ceramics such as lead zirconate titanate (PZT), and sodium potassium niobate ((K,Na)NbO3); polymers such as polyvinylidene fluoride (PVDF); and organic nono-structures such as diphenylalanine peptide nanotubes (PNTs). The main uses today for ultrasonic transducers are in medical imaging, non-destructive testing, welding, sensors and control devices. Most devices are made from PZT materials, which is an omnidirectional, polycrystalline piezoelectric material. As an omnidirectional material the crystal emits ultrasound in all directions simultaneously. As a polycrystalline material it has numerous small crystal faces in random orientations and grain boundaries between the crystals, also in random orientations.

### Medical Uses

Medical uses of ultrasound are mainly as diagnostic techniques; effective for imaging soft tissues of the body. It is used to see internal body structures such as tendons, muscles, joints, vessels and internal organs. Typical medical ultrasound instruments operate in the frequency range of 1-18 MHz, though frequencies up to 100 MHz have been used experimentally in a technique known as biomicroscopy. (See https://en.wikipedia.org/wiki/Medical_ultrasound).

In general, as frequency increases smaller feature sizes can be distinguished while range/depth of penetration decreases due to higher attenuation as frequency increases. Improving the sensitivity of ultrasound techniques while also increasing their depth of penetration would be useful.

### Non-Destructive Testing

Many non-destructive testing techniques are based on the propagation of ultrasonic waves in the object or material tested. In most common applications, very short ultrasonic pulse-waves with center frequencies ranging from 0.1-15 MHz, and occasionally up to 50 MHz, are transmitted into materials to detect internal flaws or to characterize materials. (See https://en.wikipedia.org/wiki/Ultrasonic_testing). In general, as frequency increases smaller feature sizes can be distinguished while range/depth of penetration decreases. This is especially true of advanced alloys, advanced ceramics, and advanced composites where the complexity of their makeup and the decreasing size of features and defects makes NDT very challenging using current techniques. Improving the sensitivity of ultrasound techniques while also increasing their depth of penetration and power would be useful.

### Welding and Joining

In ultrasonic welding of plastics, the parts are sandwiched between a fixed anvil and a horn connected to a transducer, and a low-amplitude acoustic vibration is emitted. Common frequencies used in ultrasonic welding of thermoplastics range from are 15-70 kHz. Ultrasonic waves can also be used to weld metals, but are typically limited to small welds of thin, malleable metals, e.g. aluminum, copper, nickel. (See https://en.wikipedia.org/wiki/Ultrasonic_welding). Difficulties in creating quality welds repeatedly and consistently stem from the use of lower than optimal frequencies that do not efficiently deposit the sonic energy precisely at the interfacial zone, causing only partial melting or mixing of the materials. Higher frequencies would allow precise deposition of ultrasonic energy at the interfacial zone for efficient heating.

### Sensors and Controls

In ultrasonic sensors and control devices frequencies of 10 kHz to 1 MHz are commonly used in a variety of applications like level sensors, thickness gauges, fluid flow meters, object detection, position verification, etc. The ability to achieve longer detection distances and to register results in the presence of non-homogenous materials or environments and changing conditions would be useful. Higher signal to noise ratios and means to filter undesirable frequencies would be useful.

As can be seen, the bulk of ultrasonic transducers and related applications use frequencies of less than 1 MHz. Even specialty applications top out at 100 MHz.

### Advancements and Benefits of the Present Invention

There is an inverse relationship between frequency and crystal thickness. The resonant frequency of the transducer increases as the transducer material thickness decreases. Thus, to achieve very high frequencies very thin transducers are required. Making thin transducers is difficult. Additionally, most transducer materials are polycrystalline or hetero-structured, which means that there are grain boundaries in the material that can serve as current pathways, effectively electrically shorting out the transducer as it gets thinner and thinner with increasing voltages applied. One way to overcome both of these difficulties is through the use of single crystals or homogenously structured transducer materials but fabricating bulk single crystals has been difficult to accomplish. Moreover, a single crystal does not include any grain boundaries, therefore no current pathways that can short out the transducer, meaning that no matter how thin the transducer, it will still function unless it is powered beyond its breakdown voltage; typically much higher than the operational voltage needed for the transducer to operate. Thus, single crystal ultrasonic transducers can be made very thin and therefore can achieve very high frequencies.

Single crystals with directional orientation emit ultrasonic waves in only two directions, normal to the front and rear faces of the crystal. It is thus possible to transmit more sonic energy in the desired direction for the same input energy as can be achieved with an omnidirectional transducer. The addition of Bragg reflector or phonic crystal materials will enhance this effect through filtering or reflection of the sonic energy from the rear face of the transducer enhancing the signal-to-noise ratio. This benefit of bi-directional orientation is not possible with omnidirectional piezoelectric materials.

The use of phonic crystals on the emission face of the transducer allows the transmission and reception of ultrasonic signals to be separated into independent functions. This arrangement eliminates a dead-time after an emission pulse and dramatically improves the signal-to-noise ratio, especially if the receiving function is tuned to different frequencies than the emission frequency.

Applying a DC to voltage to a wurzite III-V or II-VI crystal on its c-plane orientation will cause a corresponding dimensional change in the piezoelectric material that can be used to dynamically tune and/or vary the resonant frequency of the transducer after fabrication, with fine resolution control, for a particular material or application. This characteristic can be applied to the transducer crystal itself, or associated phononic crystals on the front or rear faces to create an ultrasonic transducer with very flexible performance characteristics capable of real-time, dynamic control of the emission frequency to account for changes in the environment or material being interrogated as well as real-time variation in focal length. These characteristics contrast with the state-of-the-art that has a fixed resonant frequency based on crystal thickness with no ability to vary or tune the resonant frequency or focal length. A non-tunable crystal operated at non-resonant frequencies performs with poor efficiency, poor signal to noise ratios, and reduced operational lifetime of the transducer.

Pixilated arrays create the ability to perform two-dimensional ultrasonic interrogations that can provide richer, more informative insights into complex material structures as compared to current one-dimensional techniques. With each pixel capable of acting independently, the transducer is capable of precise spatial and temporal control of the ultrasound emissions that can produce complex wave forms and enable time-dependent directionality for enhanced data collection and analysis techniques. This added functionality allows for interrogating a wider area simultaneously, resulting in improved speed of scanning large objects. When a pixilated array is made with each pixel having different heights and therefore different emission frequencies. it is possible to create a device capable of emitting and receiving harmonics of the primary emission frequency. This arrangement allows collection Doppler shift information simultaneously with the collection of the primary signal to allow for very high resolution images to be produced as well as to significantly reduce post-imaging processing requirements.

A pixilated array can be fabricated from piezo-electric materials that also act as p-n junctions. By varying the height of the pixels as well as an applied bias voltage a pixilated array can be created that can emit and receive a complex analog signal and produce a digital output based on what it receives. Numerous variations of this can be imagined to allow a device to be tailored to respond to a specific received signal and no other so as to significantly reducing the need and complexity of analysis of the returned signal.

The ability to produce very high frequencies; directional orientation; higher signal-to-noise ratios; and dynamic control of the ultrasound transmission and/or reception frequency and/or focal length in single crystals and/or pixilated arrays; and the digitization of the analog signal that can be tailored for specific desired responses represent significant advancements to the state-of-the-art in ultrasonic transducers and related devices and applications. These advancements independently or in various combinations enable enhanced data collection and analysis using ultrasound, potentially unlocking new applications and uses. This innovation may lead to the creation of economic opportunities in the fabrication and sale of new, advanced ultrasonic devices as well as in new applications that have the ability to improve performance, reduce energy demand, improve safety of goods and passengers, and create economic opportunity for the United States.

All of the above cited references are hereby incorporated herein by reference in their entirety, as well as U.S. patent application Ser. No. 15/446,418 entitled Stable P-Type Zinc Oxide and Bandgap Engineered Zinc Oxide and Other Oxide Systems.

### BRIEF SUMMARY OF THE INVENTION

Using a chemical vapor-phase deposition (CVD), physical vapor phase deposition (PVD) process or similar, novel directionally-oriented piezoelectric materials are created from zinc oxide (ZnO) and similar materials with innovative features that enhance their performance as ultrasonic transducers. Applications for these enhanced piezoelectric materials and transducers include: underwater sonar devices, non-destructive testing devices, tank level indicators, eddy current detectors, ultrasonic wellfield characterization devices, and in-fluid imaging devices (e.g., under-water and under-sodium viewing devices).

The present invention provides innovations in several areas that result in novel piezoelectric materials and devices with enhanced capabilities:

1. Novel piezoelectric materials and fabrication methods,

2. Methods to reduce noise and interference,

3. Parallelization of signal generation and reception,

4. Improved signal to noise ratio responsiveness,

5. Novel wave focusing, shaping, and directing methods and materials, and

6. Novel crystal structures to enhance functionality, and

7. Digital Piezoelectric Signal Detection

### DESCRIPTION OF THE DRAWINGS

The invention will be more readily understood from a reading of the following specification and by reference to the accompanying drawings forming a part thereof, wherein an example of the invention is shown and wherein:

FIG. 1 is a photographic example of the structure of a phononic crystal etched into steel including T-shape structure;

FIG. 2 is an illustration depicting phononic crystal structures;

FIG. 3 is a band gap diagram of phononic crystals made from WC and water where the lower diagram illustrates a phononic crystal that is tuned to accept only Doppler broadened sound waves;

FIG. 4 is a graphical illustration showing the depth of acoustic penetration with tunable photonic crystal structure simulated as WC (Tungsten Carbide) rods penetrating water;

FIG. 5 illustrates a notional annular-shaped phononic crystal used to control focal length of a transducer; and

FIG. 6 illustrates a notional 5×5 Pixelated Ultrasound Transducer Array.

### DESCRIPTION OF A PREFERRED EMBODIMENT

Referring now to the drawings, the invention will be described in more detail.

1. Novel Piezoelectric Materials and Fabrication Method

Directionally-oriented piezoelectric materials are formed by using a chemical vapor deposition (CVD), or similar, process to grow very thin layers (i.e., nanometer-scale) of epitaxial ZnO in the wurtzite form with the c-plane preferentially oriented upward. This technique can also be used to fabricate directionally-oriented piezoelectric crystals with other, similar III-V and II-VI materials, as well as III-O and II-O materials such as: gallium oxide and other oxides including alloys and band gap engineered materials of III-V, III-O, II-O, and II-VI materials, as well as nitrides such as gallium nitride (GaN), indium nitride (InN), and aluminum nitride (AlN), boron nitride (BN), and alloys of these. The ZnO, or other material, would be deposited on a single-crystal substrate, for example, sapphire. Other potential substrate materials include oxides, carbides, metals and others including: silica, ruby, copper, tungsten, tungsten carbide, and silicon carbide.

Because a thin wafer of piezoelectric material vibrates at a wavelength proportional to its thickness, a higher frequency is generated as the thickness of the material is reduced. This application embodies one of the first, commercially viable growth techniques for these materials using advances in semiconductor growth techniques.

The use of a CVD, or similar, process allows for very precise control of the thickness of the very thin layers of piezoelectric material deposited as a single crystal (epitaxial) on a substrate. Therefore, the ability of the CVD, or similar process such as low pressure rotating disc metal organic chemical vapor deposition (also known as metal organic vapor-phase epitaxy) to precisely control the thickness provides very tight control over the emission frequency. Because the CVD, or similar, process allows for very thin (nano-scale) coatings to be precisely applied, high-megahertz (MHz) to gigahertz (GHz) and even terahertz (THz) ultrasound frequencies can be generated. The precision and uniformity of the epitaxial layer grown using CVD, or similar, processes results in a very highly peaked waveform centered on the desired emission frequency while removing undesirable higher and lower frequency noise. Using advances in these fabrication techniques, smaller pixel sizes also become a reality increasing the spatial and depth resolution of these systems.

Additionally, the epitaxial zinc oxide crystals fabricated using the CVD, or similar, process produces a directionally-oriented piezoelectric material. One of the significant advances of this technology is that crystals grown through these processes only emit phononic energy (ultrasound waves) in one particular direction. Thus, a thin wafer of this piezoelectric material will emit ultrasonic waves in only two directions, centered on the axes normal to the two faces of the crystal. This contrasts with the commonly used lead zirconia titanate (PZT) ultrasound transducers that produce an omnidirectional signal from all cut faces of the material. Thus, these directionally-oriented zinc oxide piezoelectric transducers can provide more ultrasound energy in the desired direction for the same input energy as the current state-of-the-art.

2. Methods to Reduce Noise and Interference

It is desirable in an ultrasonic transducer to maximize signal strength and optimize power out-coupling and purity in one direction while minimizing sound transmission in all other directions so as to maximize detector efficiency while also reducing noise and interference resulting in an improved signal-to-noise ratio (SNR). Two methods are proposed to accomplish this: use of phononic crystal structures and use of a distributed Bragg phonon reflector.

Phononic Crystal

A phononic crystal material can be precisely shaped, assembled, or fabricated in one-, two- or three-dimensions and placed on the side of the piezoelectric crystal's non-emission face so as to direct ultrasound in desired directions and/or to mute sound in other or undesired directions. This enhancement would significantly reduce noise to the receiving unit and improve the SNR.

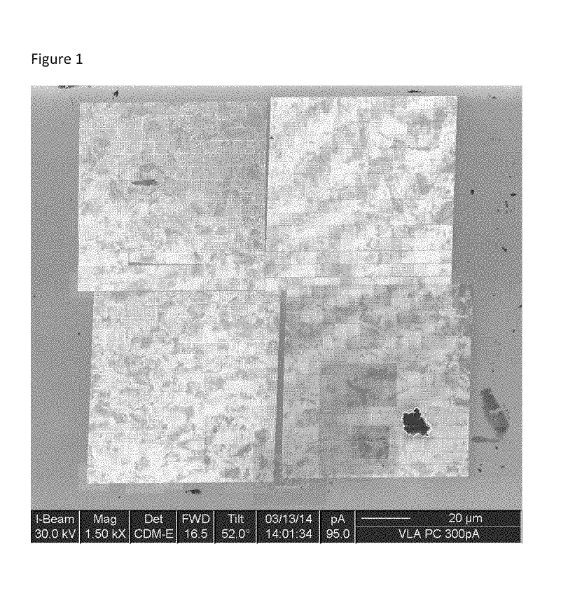

A phononic crystal is similar to a photonic crystal with the main difference being in the control of the propagation of phonons as opposed to optical photons. This is accomplished through a repeating array of hard and soft (relative to the hard) materials like hard tungsten carbide spheres in a repeating face centered cubic lattice with water interstitially filling the void spaces (See FIG. 1). The water allows phonons to resonate in certain directions and frequencies and is muted and even prohibited (destructively interfered) in others.

Hard materials that can be used to create phononic crystals include hard ceramics and/or metals and include but not limited to silica, silicon carbide, tungsten carbide, titania, and alumina. Soft materials that can be used include but are not limited to: air, water, gels, oils, and plastics molten metals and others.

The phononic crystal can be applied using a variety of methods which directly print or deposit the material onto the piezoelectric device, e.g. multi-beam photon lithography, e-beam lithography, micro-structured 3D printing, nano and micro self-assembly, and micro-extrusion techniques.

### Distributed Bragg Phonon Reflector

Alternating layers of soft polymer and hard materials can be used to form a distributed Bragg phonon reflector. A distributed Bragg reflector behaves such that sound waves of any frequency band and angle of incidence are reflected back on itself in such a way as to create destructive interference. In essence, a distributed Bragg reflector can be constructed that behaves as a mirror that reflects the sound back through the emitting crystal so as to be emitted in the preferred direction and drastically mutes any emission from the non-emission side of the device. This arrangement significantly improves the efficiency of the device.

Soft materials that can be used include but are not limited to: polymethyl methacrylate, polycarbonate, and others. Hard materials that can be used include ceramics and metals and include but are not limited to: silica, silicon carbide, tungsten carbide, titania, and alumina. The distributed Bragg phonon reflector is fabricated onto the wafer using CVD, PVD, and other standard microelectronic fabrication techniques.

3. Parallelization of Signal Generation and Reception

The piezoelectric transducer can be coupled with a two-dimensional or three-dimensional phononic crystal resonator cavity that functions as an ultrasound waveguide. The waveguide structure can be tuned to the acoustic properties of the bulk media such that improved directional out-coupling is achieved. The waveguide can be of straight, L, F, T, cross, wye, or similar configurations (See FIG. 1) depending on the application. Straight wave guide phononic crystals are well-suited for removing unwanted noise and off-spectrum frequencies. L, T, and F configurations improve the out-coupling directional nature of the ultrasonic waves while directing off-frequency Doppler-broadened signatures to sensors specifically tuned to these other wavelengths. This allows for significantly higher signal to noise ratios (SNR) on the off-spectrum frequencies generated by defects or temperature changes. This arrangement can also be used to minimize “ringing” induced from the transducer's output frequencies by directing residual emissions away from the receiver.

Also in the F, L, T, cross and similar configurations, the ultrasound emitter can be coupled in the forward direction. With proper tuning of the emitter and/or the phonic crystal, the emitted sound will only propagate down the waveguide and be emitted in a tight, focused and highly peaked waveform. The legs not aligned to the transmission direction in the L, T, cross, or similar configurations of the transducer structure can be coupled to piezoelectric transducers that function as receivers of ultrasound return signals. With proper tuning of the phonic crystal, the return signal will preferentially propagate down these legs where the receiver piezoelectric transducers are located. In this way, ultrasound emissions do not interfere with the receivers and return signals do not interact with the emitter transducer(s). In this way the SNR of the device is significantly improved, gaining tens to hundreds of decibels improved response compared with current techniques.

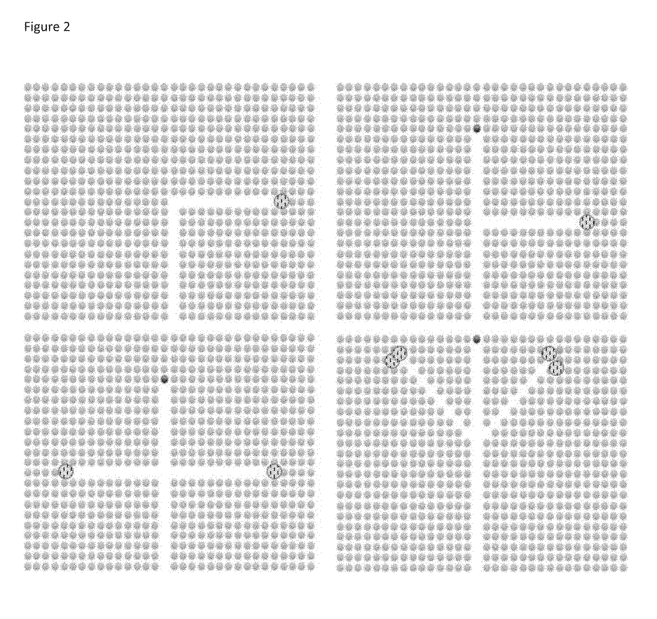

Referring now to FIG. 2, the black dots represent the emitter and the vertical hatched dots represent the receivers. The grey dots represent the hard materials of the phononic crystal and the white spaces represent the soft materials of the phononic crystal. Upper left graphic of FIG. 2 is an L configuration for decreasing the noise registered by the receiver. Upper right graphic of FIG. 2 depicts a T configuration where the signal generator is located at the top of the vertical leg and the horizontal leg is the receiver. This arrangement minimizes the noise and ring of the receiver when pulsed by the transducer. Bottom left graphic in FIG. 2 is a cross configuration where each of the two receiver legs is optimized for a higher and lower Doppler broadened signal. Lastly is the Wye configuration. This configuration allows for multiple receivers who are tuned at fractional harmonics of the sender where normal receivers are used at the legs of the Wye.

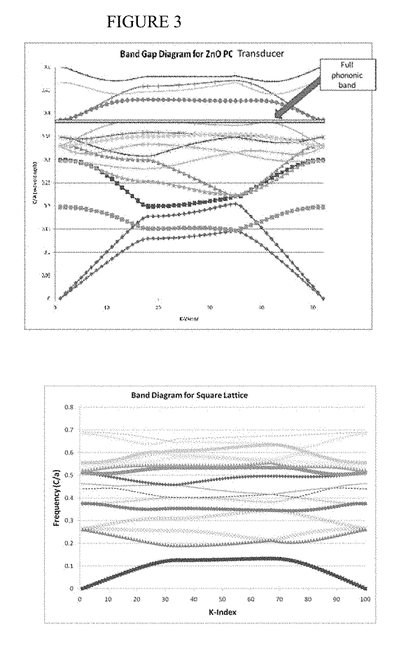

In addition, the off-transmission axis legs of the waveguide structure (of the L, T, cross, or similar) can be tuned to frequencies other than the transmitted frequency to further improve the resolution of off-frequency spectra allowing for improved Doppler broadening and eddy current measurements (See FIG. 3).

4. Improved Signal to Noise Ratio Responsiveness

Type III-V and II-VI materials (ZnO is a II-VI material) share a characteristic unique to these materials; that is, a constant electric field applied to the C plane structure of these materials will cause the crystalline lattice to expand or contract unilaterally with the applied field bias. In this way an applied DC voltage will cause a corresponding dimensional change in the piezoelectric material that can be controlled through variations in the applied voltage.

When moving to higher and higher frequency piezoelectric materials, the thickness resolution and uniformity of the piezoelectric materials becomes increasingly more important. Thus, in addition to the fine control over thickness achievable using CVD, or similar, processes described above, the constant field gradient contraction/expansion behavior provides the opportunity to achieve even finer control of emitted frequency. This contraction/expansion can be used to tune and/or vary the resonant frequency of the transducer after fabrication, with fine resolution control, for a particular material or application.

This DC field can be superimposed over an applied oscillating field, such as an AC triangular wave pattern. The AC signal produces the oscillatory behavior in the transducer while the DC field shifts or offset tunes the characteristic frequency of the transducer. The DC signal acts to shift the applied alternating current (AC) signal that is used to generate the vibrations in the piezoelectric device. This results in a shift in the emitted frequency from the piezoelectric transducer, which 1) increases the overall signal generation capability of the transducer; 2) acts to improve wall plug efficiency over a wide range of emission frequencies; and 3) allows for long service lifetimes for the transducer even when operated off its natural resonant frequency. These characteristics contrast with the very low efficiencies and reduced service life-times achieved for current materials when operated off their natural resonant frequency.

Additional control over off-frequency behavior of an ultrasonic transducer device can be achieved by adding a layer of piezoelectric material (made from III-V or II-VI materials) to the non-emission side of the transducer. Then, a constant voltage field applied to this layer will result in a shifting of the resonant frequency of the transducer. It further improves the coupling of the transducer to any applied muting material on the backside of the device including but not limited to distributed Bragg reflectors, phonic crystals, or other materials.

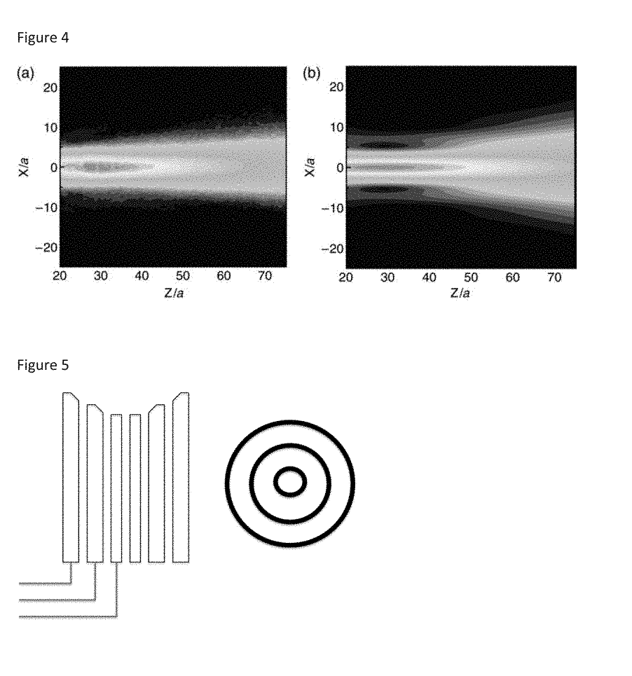

A similar technique can be applied to any phononic crystal attached to the transducer. By fabricating the phononic crystal's hard material from a III-V or II-VI material or coating the phononic crystal in III-V or II-VI materials, similar effects can be achieved in the phononic crystal. Slight variations of the pitch-spacing between the hard and soft materials in the phononic crystal can then be achieved by the applying a DC voltage to the underlying piezoelectric crystal, which causes the crystal to elongate or shrink, based on the applied voltage. The slight variation in the phononic crystal structure can be used to tune the frequency of the return spectra based on the physical properties of the media (See FIG. 4). This feature allows for dynamic, real-time tuning of both the real and imaginary components of the propagating wave allowing for polarization to be maintained and observed

5. Novel Wave Focusing, Shaping, and Directing Methods and Materials

Applying these techniques to the front-end coupling of the transmission media allows for changes in the transmission media such as salinity, temperature, density, viscosity, etc. to be compensated for in real-time, resulting in more accurate and efficient NDT or detection. But, as changes in the front end coupling are made to compensate for changes in the propagation media, so to must changes be made to the receiver embedded in the phononic crystal. For example, if the base frequency was A MHz and a change is made to maintain optimal out-coupling so that the output signal is changed to A+B MHz, then the receivers must be tuned to proportionally to optimally receive the A+B MHz signal. Since the pitch spacing in the phononic crystal varies a function of position, differing electric fields are needed in the phononic crystal to optimize the response of each unique frequency and position in the phononic crystal. This optimization is accomplished by creating zones within the phononic crystal and connecting each zone separately and independently to the electrical signal control device. Then, applying a spatially dependent field gradient can be applied to the different zones of phononic crystal thereby tuning each of their reception frequency bands to optimally receive the returning signal. In this way, temperature, density, salinity and other bulk medium changes into the transmission media can be corrected in real time to provide improved SNR of the returned responses.

In another variation, a phononic crystal applied to the emission side of the device can also serve as a variable lens to focus the emitted sound to a specific point outside the device. Selective and spatially dependent reactive ion etching creates a domed structure under which the zinc oxide, or similar material, transducer is grown.

The piezoelectric dome structure can be subjected to a DC voltage, which serves to induce a controlled deflection in the structure proportional to the applied voltage. Through the creation of an annular ring structure, with each annulus independently wired bonded out from under the transducer, different fields can be applied as a function of radius of the annulus under the transducer (See FIG. 5).

Applying different DC fields to these annuli, different degrees of convex, concave, and complex second and third harmonic structures become possible in the phononic crystal lens. This controlled deflection can be used to focus the sound emission of the transducer to a variety of focal lengths depending on the voltage applied. Using this technique the focal length of the transducer with a variable emission frequency as described above can be optimized for the desired emission frequency thereby maintaining efficiency while permitting variability in emission frequency. In this way, an applied DC voltage allows for tuning the device for the transmission media in which the device is located and for controlling the focal length in situ and real time as opposed to the traditional method of controlling the focal length, which uses precision-ground glass lenses; that are fixed once they are applied and need to be swapped out to change a device's focal length.

By simultaneously being able to vary the resonant frequencies and the focal length, and the improved SNR when incorporating either the variable focal length lens or phononic crystal structures, a piezoelectric transducer can be fabricated whose depth of field can be controlled in real-time, in situ.

6. Novel Crystal Structures to Enhance Functionality

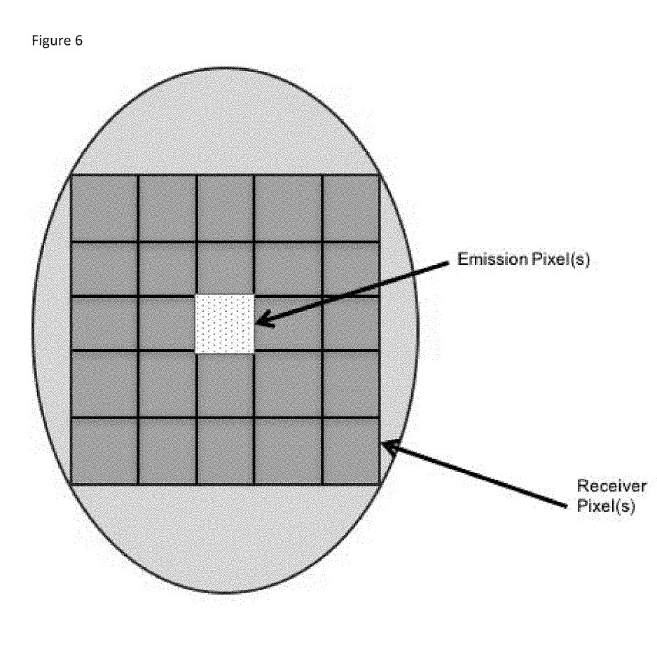

A variation of the fabrication process described in section 1 above involves the use of reactive ion etching or laser machining techniques to create a pixelated array of mesa-like structures of the ZnO (or other) directionally-oriented, piezoelectric crystal (see FIG. 6). The resulting mesas can be of uniform or of varying heights, with each mesa having an emission frequency that is defined by its height. Each of the mesas is then attached to the voltage source using micro-scale wire bonding techniques. In this way an array of micro-scale and even nano-scale piezoelectric transducers can be created with a single emission frequency or a number of different emission frequencies depending on the height of each pixel.

Pixelated arrays create the ability to perform two-dimensional (2D) ultrasonic interrogations that can provide richer, more informative insights into complex material structures significantly faster as compared to the current 1D technique. With each pixel capable of acting independently, the transducer is capable of precise spatial and temporal control of the ultrasound emissions and receptions, complex wave forms, and time-dependent directionality that enable enhanced data collection and analysis. These capabilities result in greater precision and resolution in identifying and locating subsurface features and defects. Additionally, this added functionality allows for interrogating a wider area simultaneously, resulting in improved speed of scanning large objects while simultaneously providing the other advantages of the transducers described above, e.g. higher resolution images.

Additionally, choosing emission frequencies (by varying the height of the pixels) to be harmonics of the primary emission frequency allows the device to collect Doppler shift information of the signal simultaneously with the collection of the image. This height variation of pixels allows for a variety of frequencies to be emitted that act complementarily to allow for very high resolution images to be produced as well as to significantly reduce post-imaging processing requirements.

A directionally-oriented, pixelated, piezoelectric ultrasound transducer device can be used in conjunction with the novel wave focusing, shaping, and directing methods and materials described above.

7. Digital Piezoelectric Signal Detection

Another variation of this process would involve making the piezoelectric crystal using a ZnO diode structure made from a layer of p-type ZnO (or other p-type material such as p-type gallium nitride) deposited on a layer of n-type ZnO (or other n-type material with a similar crystal lattice structure, e.g., gallium-doped zinc oxide). Reactive ion etching is used to create a pixelated array of mesa-like structures with uniform or differing heights, with each pixel connected separately to the voltage source with a micro-wire as described above. An ultrasound signal is created from an analog transmitter made from materials described above. The array of P-N diodes is then reverse-biased with a DC voltage below its band gap. As the DC signal applied to the diode interacts with the ultrasound wave causing deformations in the diode structure the band gap required to open and/or close the diode shifts. This allows the device to function as a digital switch or digital band-pass filter with a very distinct resonant frequency. As the piezoelectric crystal deflects in the A-plane, C-plane, and/or R-plane, the bandgap of the diode structure in each of the mesas changes proportionally to its deflection, thereby changing the voltage needed to trigger the opening of the diode gate of that pixel providing a digital output signal between 1 and 5 volts to the digital control system. This means that the timing of the reception of the emission returns can be linked to and controlled by the oscillation of the overall crystal. Thus, a complex analog return signal can be reduced to a series of digital, binary on-off output signals depending on whether or not the pixel was triggered at the particular frequency for which it was tuned based on its height and the voltage bias applied improving the timing resolution of the overall system. This transformation enhances the imaging resolution and speed of acquiring large sample areas. This arrangement removes the necessity for complex analog signal pulse processing for the determination of the location and type of defects being interrogated using NDT allowing for rapid signal analysis and efficient interrogation of the material. For example, a band pass filter for a Doppler-broadened or compressed ultrasonic signature can be digitally quantified without the need to do complex analog waveform fitting. In this way, a device can be created that can be designed to look for very specific signal patterns that triggers a response only if that pattern is detected, e.g., one type of crack or defect, fluid density change, or thermal gradient change in a material. This feature significantly improves the efficiency and accuracy of NDT for complex materials.

This diode structured piezoelectric transducer can be coupled with the novel wave focusing, shaping, and directing methods and materials described above.

Although the present invention has been described in considerable detail with reference to certain preferred versions thereof, other versions are possible. Therefore, the spirit and scope of the appended claims should not be limited to the description of the preferred versions contained herein. All features disclosed in this specification may be replaced by alternative features serving the same, equivalent or similar purpose, unless expressly stated otherwise. Thus, unless expressly stated otherwise, each feature disclosed is one example only of a generic series of equivalent or similar features.

1. A method of forming directionally oriented piezoelectric materials, said method comprising the steps of:
providing a single crystal substrate;
determining a desired emission frequency
depositing an epitaxial coating material onto said substrate so that the thickness of said epitaxial coating is controlled and is correlated with said desired emission frequency.

2. The method of forming directionally oriented piezoelectric materials set forth in claim 1, wherein said substrate is selected from the group consisting of sapphire, oxides, carbides, metals, silica ruby, copper, tungsten, tungsten carbide and silicon carbide.

3. The method of forming directionally oriented piezoelectric materials set forth in claim 1, wherein said epitaxial coating material is selected from the group consisting of ZnO, gallium oxide, gallium nitride, indium nitride, aluminum nitride, boron nitride, and alloys of said group.

4. The method of forming directionally oriented piezoelectric materials set forth in claim 1, wherein said step of depositing said epitaxial coating material onto said substrate includes the step of using a chemical vapor deposition capable of operation from kHz to THz frequencies.

5. The method of forming directionally oriented piezoelectric materials set forth in claim 1, wherein said epitaxial coating material or bulk wafer material capable of operation from kHz to THz frequencies is created from a diode structure tuned to specifically detect certain sizes, shapes, densities, hardness or location of a given subset of materials.

6. A directionally oriented ultrasonic transducer comprising;
A wafer made from piezoelectric material;
a phononic crystal material applied to said wafer, wherein said phononic crystal material includes an alternating array of a first material having a first hardness and a second material having a second hardness,
wherein said phononic crystals resonate in specific directions and frequencies and are muted in other directions.

7. The directionally oriented ultrasonic transducer set forth in claim 6, wherein said first material is selected from the group consisting of silica, silicon carbide, tungsten carbide, titania and alumina.

8. The directionally oriented ultrasonic transducer set forth in claim 6, wherein said second material is selected from the group consisting of: air, water, gels oils, plastics, and molten metals.

9. An ultrasonic system comprising:
a piezoelectric transducer having a phononic crystal material including an alternating array of a first material having a first hardness and a second material having a second hardness;
a phononic crystal resonator wave guide, wherein said phononic crystal resonator wave guide receives emitted frequencies from said piezoelectric transducer.

10. The ultrasonic system set forth in claim 9, wherein said phononic crystal resonator wave guide is configured from the group consisting of a straight, L, F, T, cross and wye configurations.

11. A method for varying frequency of a directionally oriented ultrasonic transducer comprising the steps of;
providing a wafer made from piezoelectric material, wherein said piezoelectric material is tuned to a first frequency;
changing said first frequency to a second frequency by applying a DC bias so that said piezoelectric material expands or contracts in proportion to said applied DC bias.

12. The method for varying frequency of a directionally oriented ultrasonic transducer set forth in claim 11, further comprising the steps of:
providing a wave form generator
varying voltage of said DC bias to sweep through a desired frequency range and simultaneously varying output frequency and wave shape emitted from said wave form generator.

13. A directionally oriented ultrasonic transducer comprising:
a wafer made from piezoelectric material;
a concentric ring structure fabricated into said wafer, wherein said concentric ring structure can be biased independently to create a variable focal length transducer to dynamically scan multiple depths into a sample in real time.
